(19) United States
(12) Patent Application Publication
(10) Pub. No.: US 2024/0324125 A1
(43) Pub. Date: Sep. 26, 2024

(54) SUPPORT MEMBER, DISPLAY APPARATUS INCLUDING THE SAME, AND METHOD OF MANUFACTURING SUPPORT MEMBER

(71) Applicants: Samsung Display Co., LTD., Yongin-si (KR); Inha University Research And Business Foundation, Incheon (KR)

(72) Inventors: Taewoong KIM, Yongin-si (KR); Hyoungjin CHOI, Incheon (KR); Qi LU, Incheon (KR); Chaewon PARK, Incheon (KR); Sanghyeok SEO, Incheon (KR); Seokjun OH, Incheon (KR); Shizhao WANG, Incheon (KR)

(21) Appl. No.: 18/614,166

(22) Filed: Mar. 22, 2024

(30) Foreign Application Priority Data
Mar. 24, 2023 (KR) 10-2023-0039180
Jul. 4, 2023 (KR) 10-2023-0086720

(51) Int. Cl. H05K 5/02

(52) U.S. Cl. CPC H05K 5/0217

(57) ABSTRACT

A support member includes a variable stiffness layer including an electrorheological elastomer, a first electrode layer disposed on a first surface of the variable stiffness layer, and a second electrode layer disposed on a second surface of the variable stiffness layer different from the first surface of the variable stiffness layer.

This application claims priority to Korean Patent Application No. 10-2023-0039180, filed on Mar. 24, 2023, and Korean Patent Application No. 10-2023-0086720, filed on Jul. 4, 2023, and all the benefits accruing therefrom under 35 U.S.C. § 119, the content of which in their entirety is herein incorporated by reference.

### BACKGROUND

### 1. Field

Embodiments relate to a support member for a display apparatus, a display apparatus including the same, and a method of manufacturing the support member for a display apparatus, and more particularly, to a support member for a display apparatus, which may improve display quality, a display apparatus including the same, and a method of manufacturing the support member for a display apparatus.

### 2. Description of the Related Art

Recently, along with the development of display apparatus-related technologies, research on and development of flexible display apparatuses to be bent or rolled into a roll shape are being conducted. Among such devices, a rollable display apparatus is advantageously and easily stored and used by winding a flexible display using a shaft or the like as a central axis during storage and unfolding and using the flexible display during use.

To support an unfolded flexible display panel, the rollable display apparatus includes a support member disposed below the display panel. The support member includes an elastic layer and metal bars located in the elastic layer to support the display panel.

### SUMMARY

However, in such a support member according to the related art, a step difference is recognized visually in a region between the metal bars, and thus, display quality is degraded.

Embodiments include a support member for a display apparatus, which may improve display quality, a display apparatus including the same, and a method of manufacturing the support member for a display apparatus. However, the objective is an example, and the scope of the disclosure is not limited thereby.

Additional embodiments will be set forth in part in the description which follows and, in part, will be apparent from the description, or may be learned by practice of the presented embodiments of the disclosure.

In an embodiment of the disclosure, a support member includes a variable stiffness layer including an electrorheological elastomer, a first electrode layer disposed on a first surface of the variable stiffness layer, and a second electrode layer disposed on a second surface of the variable stiffness layer different from the first surface of the variable stiffness layer.

In an embodiment, the electrorheological elastomer may include an elastic layer and dielectric particles disposed within the elastic layer.

In an embodiment, the dielectric particles may each include titanium dioxide.

In an embodiment, the dielectric particles may each have a predetermined surface area of about 380.00 square meters per gram (m²/g) to about 420.00 m²/g.

In an embodiment, the dielectric particles may each include a plurality of pores, an average of sizes of the plurality of pores may be about 2.25 nanometers (nm) to about 2.55 nm, and a volume of the plurality of pores may be about 0.20 cubic centimeter per gram (cm³/g) to about 0.30 cm³/g.

In an embodiment, the dielectric particles may each include urea and strontium titanyl oxalate.

In an embodiment, a mass ratio of the dielectric particles to a total mass of the variable stiffness layer may be about 60% to about 70%.

In an embodiment, the elastic layer may include polydimethylsiloxane.

In an embodiment of the disclosure, a display apparatus includes a display panel including a display element, and a support member disposed below the display panel, wherein the support member includes a variable stiffness layer including an electrorheological elastomer, a first electrode layer disposed on a first surface of the variable stiffness layer, and a second electrode layer disposed on a second surface of the variable stiffness layer different from the first surface of the variable stiffness layer.

In an embodiment, the variable stiffness layer may include dielectric particles and an elastic layer in which the dielectric particles are disposed.

In an embodiment, the dielectric particles may each include titanium dioxide.

In an embodiment, the dielectric particles may each have a predetermined surface area of about 380.00 m²/g to about 420.00 m²/g.

In an embodiment, the dielectric particles may each include a plurality of pores, an average of sizes of the plurality of pores may be about 2.25 nm to about 2.55 nm, and a volume of the plurality of pores may be about 0.20 cm³/g to about 0.30 cm³/g.

In an embodiment, the dielectric particles may each include urea and strontium titanyl oxalate.

In an embodiment, a mass ratio of the dielectric particles to a total mass of the variable stiffness layer may be about 60% to about 70%.

In an embodiment, the elastic layer may include polydimethylsiloxane.

In an embodiment, the display apparatus may further include an adhesive layer disposed between the display panel and the support member.

In an embodiment of the disclosure, a method of manufacturing a support member includes providing a variable stiffness layer including an electrorheological elastomer, forming a first electrode layer on a first surface of the variable stiffness layer, and forming a second electrode layer on a second surface of the variable stiffness layer different from the first surface of the variable stiffness layer.

In an embodiment, the providing the variable stiffness layer may include forming dielectric particles from a first solution including titanium alkoxide, polyvinylpyrrolidone, alcohol, organic acid, and deionized water, and forming the electrorheological elastomer by dispersing the dielectric particles and a curing agent in a polydimethylsiloxane solution, and then curing the polydimethylsiloxane solution.

In an embodiment, a volume ratio of titanium butoxide to ethanol in the first solution may be about 1:1.5 to about 1:2.5.

In an embodiment, the providing the variable stiffness layer may include forming dielectric particles by forming strontium titanyl oxalate particles from a second solution including titanium halide, strontium halide, oxalic acid, and deionized water, and then coating the strontium titanyl oxalate particles with urea, and forming the electrorheological elastomer by dispersing the dielectric particles and a curing agent in a polydimethylsiloxane solution, and then curing the polydimethylsiloxane solution.

In an embodiment, a mass ratio of the dielectric particles to a total mass of the variable stiffness layer may be about 60% to about 70%.

Other features and merits other than those described above will become clear from the detailed description, claims, and drawings for carrying out the disclosure below.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a plan view schematically illustrating an embodiment of a display apparatus;

FIG. 2 is a schematic cross-sectional view of the display apparatus taken along line I-I′ of FIG. 1;

FIG. 3 is a schematic enlarged cross-sectional view showing a region A of FIG. 2;

FIGS. 4A to 4C are microscope images of an embodiment of titanium dioxide (TiO₂) particles included in a support member of a display apparatus;

FIGS. 5A to 5D are microscope images of an embodiment of a urea-coated strontium titanyl oxalate (SrTiO(C₂O₄)₂ (“USTO”) particle included in a support member of a display apparatus;

FIG. 6 is a flowchart for explaining an embodiment of a method of manufacturing a support member for a display apparatus;

FIG. 7 is a graph showing an embodiment of a storage modulus of a support member for a display apparatus;

FIG. 8 is a graph showing an embodiment of an electrorheological efficiency of a support member for a display apparatus;

FIG. 9 is a graph showing an embodiment of a storage modulus of a support member for a display apparatus; and

FIG. 10 is a graph showing an embodiment of an electrorheological efficiency of a support member for a display apparatus.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating embodiments are referred to gain a sufficient understanding of embodiments, the merits thereof, and the objectives accomplished by the implementation of the disclosure. However, the disclosure is not limited to the embodiments disclosed below, but may be implemented in various different forms.

In this specification, terms such as first and second are used for the purpose of distinguishing one component from another component without a limiting meaning.

The singular expressions in the specification include the plural expressions unless clearly specified otherwise in context.

In this specification, terms such as “include” or “have” represent that the features or elements described in the specification exist, and do not preclude the possibility that one or more other features or elements may be added.

In this specification, the expression “A and/or B” represents the case of A, B, or A and B. In addition, the expression “at least one of A and B” represents the case of A, B, or A and B.

In this specification, when various components such as a layer, a film, a region, and a plate are referred to as being “on” other components, this includes the case in which the components is “directly on” other components as well as the case in which other components are located therebetween.

In this specification, when films, regions, components, and the like are connected, this includes the case in which films, regions, and components are directly connected, or/and the case in which other films, regions, and components are located between the films, regions, and components. For example, when a film, a region, a component, and the like are electrically connected in this specification, this represents the case in which a film, a region, a component, and the like are directly electrically connected, and/or indirect electrical connection in which another film, region, component, and the like are located therebetween.

In this specification, the x-axis, y-axis, and z-axis are not limited to the three axes of the Cartesian coordinate system, and may be interpreted in a broad sense including them. For example, the x-axis, y-axis, and z-axis may be orthogonal to each other, but may refer to different directions that are not orthogonal to each other.

In this specification, when an embodiment is otherwise embodied, a specific process order may be performed differently from the described order. For example, two processes described in succession may be performed substantially simultaneously, or may be performed in an order opposite to the order described.

In this specification, the expression “in a plan view” refers to the case in which a target portion is viewed from above. That is, in this specification, the expression “in a plan view” may refer to “when viewed from a direction perpendicular to a substrate 110”.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments will be described in detail with reference to the accompanying drawings, and when describing with reference to the drawings, the same or corresponding components are given the same reference numerals, and repeated descriptions thereof will be omitted. For convenience of explanation, in the drawings, the size of components may be exaggerated or reduced. For example, the size and thickness of each component shown in the drawings are arbitrarily shown for convenience of description, and thus the present disclosure is not necessarily limited to the drawings.

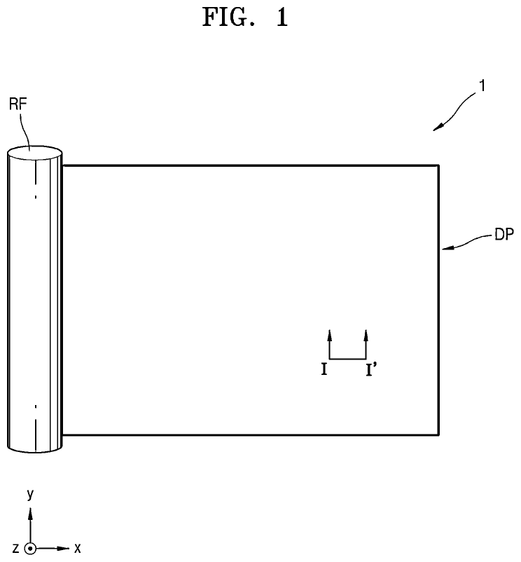

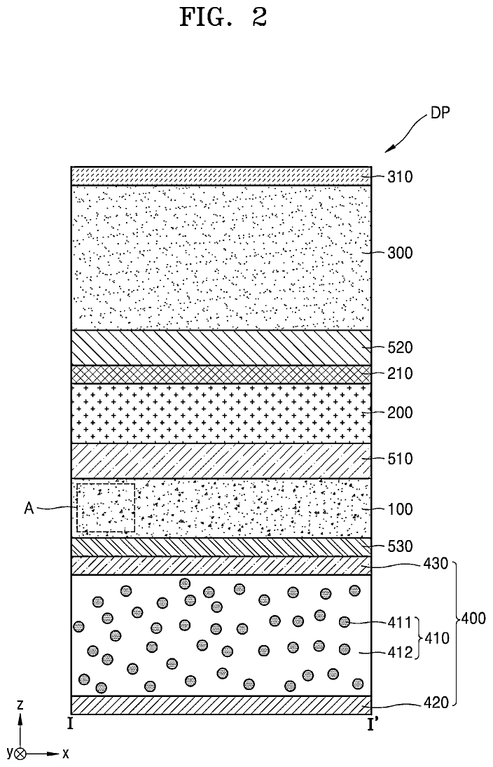

FIG. 1 is a plan view schematically illustrating an embodiment of a display apparatus 1. FIG. 2 is a schematic cross-sectional view of the display apparatus taken along line I-I′ of FIG. 1.

As shown in FIG. 1, the display apparatus 1 in an embodiment may be a rollable display apparatus. In detail, the display apparatus 1 in an embodiment may include a roll frame RF and a display DP wound in a roll form within the roll frame RF. That is, FIG. 1 shows the display apparatus 1 in a state in which the display DP is unfolded.

The roll frame RF may include a shaft (not shown) therein. The shaft (not show) may be combined with one end of the display DP, and the display DP may be wound around the shaft (not shown) as a central axis. To this end, the display DP may be flexible.

As shown in FIG. 2, the display DP may include a display panel 100, a window 200, a first coating layer 210, a protective film 300, a second coating layer 310, and a support member 400. The display DP may further include a first adhesive layer 510, a second adhesive layer 520, and a third adhesive layer 530 that connect the components to each other.

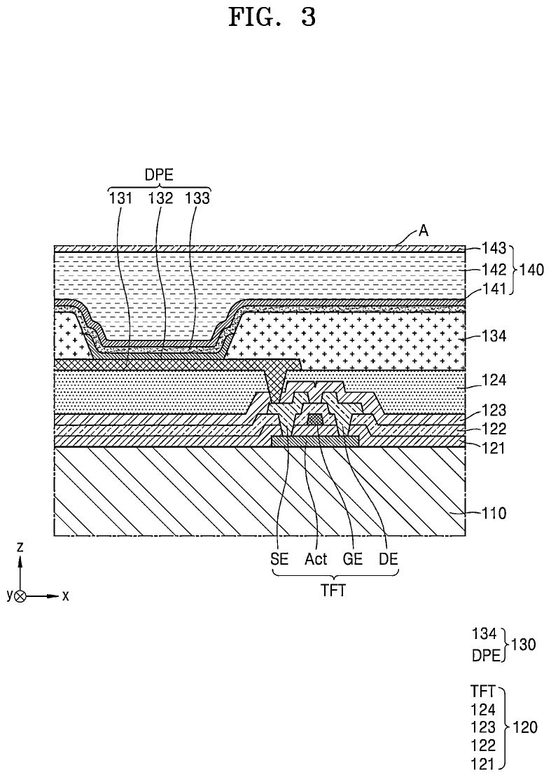

The display panel 100 may be disposed below the window 200. The display panel 100 may include a display element and a transistor electrically connected to the display element. In detail, as shown in FIG. 3 that is an enlarged cross-sectional view schematically illustrating a region A of FIG. 2, the display panel 100 may include the substrate 110, a transistor layer 120, a display element layer 130, and an encapsulation layer 140.

The substrate 110 may include various materials having flexible or bendable characteristics. In an embodiment, the substrate 110 may include glass, metal, or polymer resin, for example. The substrate 110 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 110 may be modified in various ways, and for example, may have a multilayer structure that includes two layers each having such a polymer resin and a barrier layer having an inorganic material (silicon oxide, silicon nitride, silicon oxynitride, or the like) disposed between the layers. In some cases, a thin metal foil such as steel use stainless (“SUS”) may also be used in the substrate 110.

The transistor layer 120 may be disposed above the substrate 110. The transistor layer 120 may include a thin film transistor TFT, a first inter-insulation layer 121, a second inter-insulation layer 122, a third inter-insulation layer 123, and a planarization layer 124.

The thin film transistor TFT may include a semiconductor layer Act, a gate electrode GE, a source electrode SE, and a drain electrode DE, which include amorphous silicon, polycrystalline silicon, an oxide semiconductor material or an organic semiconductor material. To ensure insulation between the semiconductor layer Act and the gate electrode GE, the first inter-insulation layer 121 including or consisting of an inorganic material such as silicon oxide, silicon nitride and/or silicon oxynitride may be disposed between the semiconductor layer Act and the gate electrode GE. The second inter-insulation layer 122 including or consisting of an inorganic material such as silicon oxide, silicon nitride, and/or silicon oxynitride may be disposed above the gate electrode GE, and the third inter-insulation layer 123 may be disposed to cover the source electrode SE and the drain electrode DE. As such, the insulating layer including or consisting of an inorganic material may be formed via chemical vapor deposition (“CVD”) or atomic layer deposition (“ALD”). The planarization layer 124 may be disposed above the thin film transistor TFT. The planarization layer 124 may substantially planarize an upper portion of the thin film transistor TFT. The planarization layer 124 may include an organic material such as acrylic, polyimide, benzocyclobutene (“BCB”), or hexamethyldisiloxane (“HMDSO”), for example. FIG. 3 shows the planarization layer 124 as a single layer, but the planarization layer 124 may be modified in various ways such as multiple layers.

The display element layer 130 may be disposed above the transistor layer 120. The display element layer 130 may include a display element DPE and a pixel definition film 134. The display element DPE may be, e.g., an organic light-emitting diode including a pixel electrode 131, a counter electrode 133, and an intermediate layer 132 disposed therebetween and including an emission layer. The display element DPE may be electrically connected to the thin film transistor TFT of the transistor layer 120. Electrical connection between the display element DPE and the thin film transistor TFT may be understood as electrical connection between a pixel electrode 131 of the organic light-emitting diode and the thin film transistor TFT.

As shown in FIG. 3, the pixel electrode 131 contacts one of the source electrode SE and the drain electrode DE through an opening defined in the planarization layer 124 or the like and is electrically connected to the thin film transistor TFT. The pixel electrode 131 includes a light-transmitting conductive layer including a light-transmitting conductive oxide such as indium tin oxide (“ITO”), In₂O₃, or indium zinc oxide (“IZO”), and a reflective layer including metal such as Al or Ag. In an embodiment, the pixel electrode 131 may have a three-layer structure of ITO/Ag/ITO, for example.

The pixel definition film 134 may be disposed above the planarization layer 124. The pixel definition film 134 defines an opening corresponding to each pixel, that is, an opening through which at least a central portion of the pixel electrode 131 is exposed, thereby defining pixels. As shown in FIG. 3, the pixel definition film 134 increases a distance between an edge of the pixel electrode 131 and the counter electrode 133 above the pixel electrode 131, thereby preventing an arc from being generated at the edge of the pixel electrode 131. The pixel definition film 134 may include an organic material such as polyimide or HMDSO, for example.

The intermediate layer 132 of the organic light-emitting diode may include a relatively low or relatively high molecular weight material. When the intermediate layer 132 includes a relatively low molecular weight material, the intermediate layer 132 may have a single or complex structure formed by stacking a hole injection layer (“HIL”), a hole transport layer (“HTL”), an emission layer (“EML”), an electron transport layer (“ETL”), and an electron injection layer (“EIL”) and may be formed using a vacuum deposition method. When the intermediate layer 132 includes a relatively high molecular weight material, the intermediate layer 132 may have a structure including a HTL and an EML. In this case, the HTL may include poly(3,4-ethylenedioxythiophene) (“PEDOT”), and the EML may include a polyphenylene vinylene (“PPV”)-based and polyfluorene-based relatively high molecular weight material. The intermediate layer 132 may be formed via screen printing, inkjet printing, laser induced thermal imaging (“LITI”), or the like. Needless to say, the intermediate layer 132 is not necessarily limited thereto and may have various structures. The intermediate layer 132 may include a layer unitary across the plurality of pixel electrodes 131 or may include a layer patterned to correspond to each of the plurality of pixel electrodes 131.

The counter electrode 133 may be unitary in a plurality of organic light-emitting diodes to correspond to the plurality of pixel electrodes 131. The counter electrode 133 may include a light-transmitting conductive layer including ITO, In₂O₃, or IZO, and may also include a semitransparent film including metal such as Al or Ag. In an embodiment, the counter electrode 133 may include a semitransparent film including Mg or Ag, for example.

The encapsulation layer 140 may be disposed above the display element layer 130. That is, the organic light-emitting diode may be easily damaged by moisture or oxygen from the outside, and thus the encapsulation layer 140 may cover and protect these organic light-emitting diodes. As shown in FIG. 3, the encapsulation layer 140 may include a first inorganic encapsulation layer 141, an organic encapsulation layer 142, and a second inorganic encapsulation layer 143.

The first inorganic encapsulation layer 141 may cover the counter electrode 133 and may include silicon oxide, silicon nitride, and/or silicon oxynitride. Needless to say, as desired, other layers such as a capping layer may be disposed between the first inorganic encapsulation layer 141 and the counter electrode 133. The first inorganic encapsulation layer 141 is formed along a lower structure, and thus a top surface thereof is not flat, as shown in FIG. 3. The organic encapsulation layer 142 may cover the first inorganic encapsulation layer 141, and unlike the first inorganic encapsulation layer 141, a top surface of the organic encapsulation layer 142 may be made approximately flat. The organic encapsulation layer 142 may include one or more materials selected from the group consisting of polyethylene terephthalate, polyethylene naphthalate, polycarbonate, polyimide, polyethylene sulfonate, polyoxymethylene, polyarylate, and hexamethyldisiloxane. The second inorganic encapsulation layer 143 may cover the organic encapsulation layer 142 and may include silicon oxide, silicon nitride, and/or silicon oxynitride.

As such, the encapsulation layer 140 includes the first inorganic encapsulation layer 141, the organic encapsulation layer 142, and the second inorganic encapsulation layer 143, and thus even when cracks are generated in the encapsulation layer 140 through such a multilayer structure, such cracks may be prevented from being connected to each other between the first inorganic encapsulation layer 141 and the organic encapsulation layer 142 or between the organic encapsulation layer 142 and the second inorganic encapsulation layer 143. Through this, formation of a path through which moisture or oxygen from the outside penetrates into the display apparatus 1 may be prevented or minimized.

Although not shown, the display panel 100 may further include a polarization layer (not shown) and/or a touch screen layer (not shown) disposed above the encapsulation layer 140.

The polarization layer may transmit only light vibrating in the same direction as a polarization axis among light beams emitted from the display element DPE, and absorb or reflect light vibrating in other directions. The polarization layer may include a retardation film that converts linearly polarized light into circularly polarized light or converts circularly polarized light into linearly polarized light by applying a retardation of λ/4 to two mutually perpendicular polarization components, and a polarizing film that aligns a direction of light passing through the retardation film, divides the light into two polarization components, passes only one component, and absorbs or disperses the other component.

The touch screen layer may include a touch sensor in which a first touch electrode and a second touch electrode are alternately arranged. In an embodiment, the touch sensor may be a capacitive type that detects a change in capacitance generated from a plurality of first touch electrodes and a plurality of second touch electrodes that are formed to cross each other and determines whether the corresponding portion is in contact, for example.

The window 200 may be disposed above the display panel 100. The window 200 may be attached to the display panel 100 by the first adhesive layer 510. The first adhesive layer 510 may include an optical clear adhesive (“OCA”) or a pressure sensitive adhesive (“PSA”). The first coating layer 210 may be disposed on the window 200. The first coating layer 210 may be a hard coating layer.

The protective film 300 may be disposed above the first coating layer 210. The protective film 300 may be attached to the first coating layer 210 by the second adhesive layer 520. The second adhesive layer 520 may include an OCA or a PSA. The second coating layer 310 may be disposed on the protective film 300. The second coating layer 310 may be a hard coating layer or an anti-fingerprint layer.

The support member 400 may be disposed below the display panel 100. The third adhesive layer 530 may be disposed between the display panel 100 and the support member 400. The third adhesive layer 530 may include an OCA or a PSA. That is, the support member 400 may be attached to the display panel 100 by the third adhesive layer 530. The display panel 100 may be flexible, and the support member 400 disposed below the display panel 100 may support the display panel 100 in a state in which the display DP is unfolded.

The support member 400 may include a variable stiffness layer 410, a first electrode layer 420, and a second electrode layer 430. The variable stiffness layer 410 may include an electrorheological elastomer. Therefore, characteristics such as stiffness of the variable stiffness layer 410 may be changed as voltage is applied thereto. In detail, the electrorheological elastomer included in the variable stiffness layer 410 may include a material having elasticity and a polarizable dielectric material disposed in the material having elasticity. That is, the variable stiffness layer 410 may include an elastic layer 412 and dielectric particles 411.

The elastic layer 412 may include a material having elasticity. The elastic layer 412 may include at least one of natural rubber, silicone, polydimethylsiloxane, and polyurethane. The dielectric particles 411 may be disposed in the elastic layer 412. In detail, the dielectric particles 411 may be provided in plural, and the plurality of dielectric particles 411 may be approximately uniformly distributed within the elastic layer 412. The dielectric particles 411 may include a polarizable dielectric material. A detailed description of the dielectric particles 411 will be given later.

When a voltage is applied to the variable stiffness layer 410 including the electrorheological elastomer, the variable stiffness layer 410 may have stiffness. That is, when a voltage is applied to the variable stiffness layer 410, the variable stiffness layer 410 may be rigid, and when a voltage applied to the variable stiffness layer 410 is removed, the variable stiffness layer 410 may be flexible. Accordingly, characteristics such as stiffness of the variable stiffness layer 410 may be changed by applying a voltage thereto. Accordingly, when a voltage is applied to the variable stiffness layer 410, the variable stiffness layer 410 may support the display panel 100 or the like above the variable stiffness layer 410. When a voltage applied to the variable stiffness layer 410 is removed, the display DP including the variable stiffness layer 410 and the display panel 100 may be wound.

In other words, when a voltage is applied to the variable stiffness layer 410, the electrorheological elastomer included in the variable stiffness layer 410 may have stiffness. That is, when a voltage is applied to the electrorheological elastomer, the electrorheological elastomer may have stiffness. In detail, when a voltage is applied to the electrorheological elastomer, the electrorheological elastomer may be rigid. When the voltage applied to the electrorheological elastomer is removed, the stiffness of the electrorheological elastomer may return to an original state thereof. In detail, when the voltage applied to the electrorheological elastomer is removed, the electrorheological elastomer may be flexible.

In detail, when a voltage is applied to the variable stiffness layer 410, the dielectric particles 411 included in the variable stiffness layer 410 may be polarized. That is, each of the dielectric particles 411 has a dipole moment, and thus strong attraction may be generated between the dielectric particles 411. Therefore, the variable stiffness layer 410 may be rigid. When the voltage applied to the variable stiffness layer 410 is removed, the dielectric particles 411 may return to a non-polarized state. The elastic layer 412 included in the variable stiffness layer 410 includes a material having elasticity, and thus the variable stiffness layer 410 may be flexible.

The first electrode layer 420 may be disposed on one surface of the variable stiffness layer 410, and the second electrode layer 430 may be dispose on another surface of the variable stiffness layer 410. That is, the variable stiffness layer 410 may be disposed between the first electrode layer 420 and the second electrode layer 430. FIG. 2 shows the case in which the first electrode layer 420 contacts a bottom surface (in the −z direction) of the variable stiffness layer 410 and the second electrode layer 430 contacts a top surface (in the +z direction) of the variable stiffness layer 410, but the disclosure is not limited thereto. In an embodiment, the first electrode layer 420 may be in contact in one side of the variable stiffness layer 410 and the second electrode layer 430 may contact another side surface of the variable stiffness layer 410, for example.

FIG. 2 shows the case in which the first electrode layer 420 is formed on an entirety of the surface of the bottom surface (in the −z direction) of the variable stiffness layer 410 and the second electrode layer 430 is formed on an entirety of the surface of the top surface (in the +z direction) of the variable stiffness layer 410, but the disclosure is not limited thereto. In an embodiment, the first electrode layer 420 may be formed on a portion of the bottom surface (in the −z direction) of the variable stiffness layer 410, and the second electrode layer 430 may be formed on a portion of the top surface (in the +Z direction) of the variable stiffness layer 410, for example. Hereinafter, for convenience, the following description will be given based on the case in which the first electrode layer 420 contacts the bottom surface (in the −z direction) of the variable stiffness layer 410 and the second electrode layer 430 contacts the top surface (in the +z direction) of the variable stiffness layer 410.

Although not shown, the support member 400 may further include a stiffness controller. The stiffness controller may control a voltage applied to the variable stiffness layer 410. That is, the stiffness controller may be electrically connected to the first electrode layer 420 and the second electrode layer 430 to generate an electric field between the first electrode layer 420 and the second electrode layer 430. As shown in FIG. 1, when the display DP is unwound, the stiffness controller may impart stiffness to the variable stiffness layer 410 by applying a voltage to the variable stiffness layer 410. Accordingly, the support member 400 may support the display panel 100. When the display DP is wound, the stiffness controller may impart flexibility to the variable stiffness layer 410 by removing the voltage applied to the variable stiffness layer 410. Accordingly, the display DP including the support member 400 may be wound.

The first electrode layer 420 and the second electrode layer 430 may independently include at least one of ITO, IZO, tin antinomy oxide (“TAO”), tin oxide (“TO”), zinc oxide (ZnO), graphene, carbon nanotube (“CNT”), and silver nanowire. In an alternative embodiment, the first electrode layer 420 and the second electrode layer 430 may each independently include at least one of copper (Cu), aluminum (Al), platinum (Pt), silver (Ag), gold (Au), and nickel (Ni).

In an embodiment, the dielectric particles 411 may include titanium dioxide (TiO₂). The dielectric particles 411 may be dispersed within the elastic layer 412 in a spherical or amorphous shape. The elastic layer 412 may include at least one of natural rubber, silicone, polydimethylsiloxane, and polyurethane.

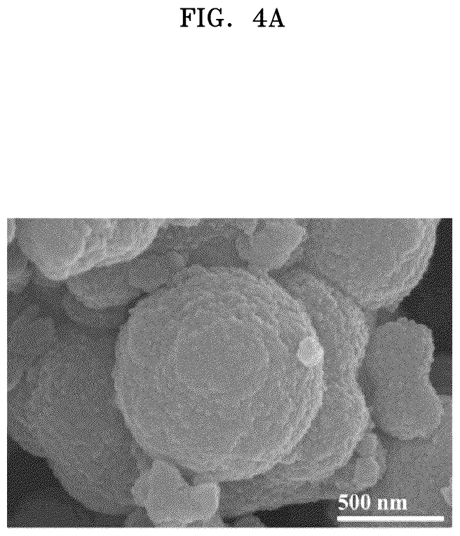

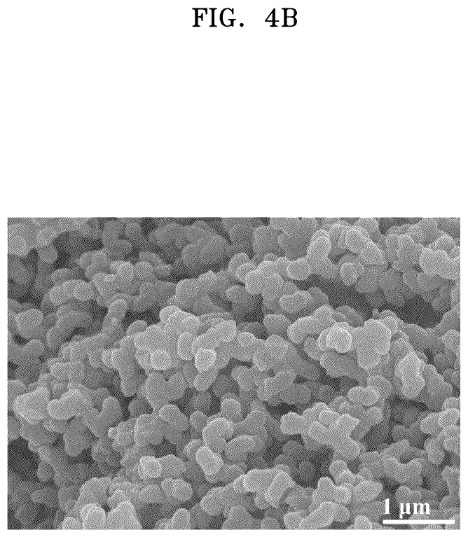

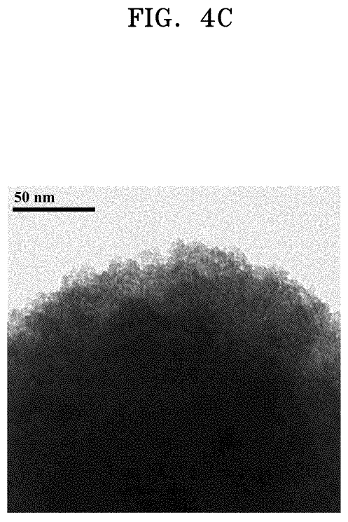

FIGS. 4A to 4C are microscope images of an embodiment of titanium dioxide (TiO₂) particles included in the support member 400 of the display apparatus 1. In detail, FIGS. 4A and 4B are scanning electron microscope images of titanium dioxide (TiO₂) particles. FIG. 4C is a transmission electron microscope image of a portion of one titanium dioxide (TiO₂) particle.

When the dielectric particles 411 include titanium dioxide (TiO₂), the dielectric particles 411 may have an approximately spherical shape. The dielectric particles 411 may have a size of about 200 nanometers (nm) to about 800 nm. In detail, the dielectric particles 411 may have a size of about 500 nm to about 700 nm. In the specification, the size of a particle or pore refers to a diameter of the particle or pore when the particle or pore is spherical, and refers to a length of a major axis of the particle or pore when the particle or pore is not spherical.

As shown in FIGS. 4A to 4C, a surface of the dielectric particles 411 may be rough. Accordingly, a surface area of the dielectric particles 411 may be large. In detail, the predetermined surface area of the dielectric particles 411 may be about 380.00 square meters per gram (m²/g) to about 420.00 m²/g. In the specification, the predetermined surface area of the dielectric particles 411 refers to a total surface area of the plurality of dielectric particles 411 per unit mass. The predetermined surface area of the dielectric particles 411 may be about 400.00 m²/g to about 410.00 m²/g. In an embodiment, the predetermined surface area of the dielectric particles 411 may be 403.39 m²/g, for example.

The dielectric particles 411 may include pores. A plurality of pores included in the dielectric particles 411 may be provided. Each of the plurality of pores may be formed on a surface of the dielectric particles 411 or inside the dielectric particles 411. A size of the pores included in the dielectric particles 411 may be about 2.25 nm to about 2.55 nm. In the specification, the size of the pores included in the dielectric particles 411 refers to an average value of sizes of a plurality of pores. The size of the pores included in the dielectric particles 411 may be about 2.30 nm to about 2.50 nm. In an embodiment, the size of the pores included in the dielectric particles 411 may be about 2.39 nm, for example.

A volume of the pores included in the dielectric particles 411 may be about 0.20 cubic centimeter per gram (cm³/g) to about 0.30 cm³/g. In the specification, the volume of the pores included in the dielectric particles 411 refers to a total volume of the pores included in the plurality of dielectric particles 411 per unit mass. The volume of the pores included in the dielectric particles 411 may be about 0.22 cm³/g to about 0.27 cm³/g. In an embodiment, the volume of the pores included in the dielectric particles 411 may be about 0.24 cm³/g, for example.

When the dielectric particles 411 have a pore size within the above range and a pore volume within the above range, the dielectric particles 411 may have a relatively large surface area. Accordingly, when an external electric field is generated between the first electrode layer 420 and the second electrode layer 430, the magnitude of polarization formed on a surface of the dielectric particles 411 may increase. That is, when a voltage is applied to the variable stiffness layer 410, the magnitude of polarization formed on the surface of the dielectric particles 411 may increase. Accordingly, when a voltage is applied to the variable stiffness layer 410, the variable stiffness layer 410 may have relatively great stiffness.

In an embodiment, the dielectric particles 411 may include strontium titanyl oxalate (SrTiO(C₂O₄)₂ (hereinafter referred to as “STO”). When the dielectric particles 411 includes STO, the dielectric particles 411 may further include urea. In detail, the dielectric particles 411 may be STO particles coated with urea (hereinafter referred to as “USTO”). That is, the dielectric particles 411 may have a structure in which a coating layer including urea is disposed above the STO particles.

In general, STO particles not coated with urea include or consist of moisture, and the electrical properties of the STO particles may vary depending on the moisture contained therein. However, the amount of moisture contained in USTO particles obtained by coating STO particles with urea may be less than the amount of moisture contained in STO particles not coated with urea. Therefore, USTO particles are less affected by moisture than STO particles that are not coated with urea, and may have reproducible electrical properties. Accordingly, when the dielectric particles 411 are USTO particles, the variable stiffness layer 410 may have reproducible electrical properties.

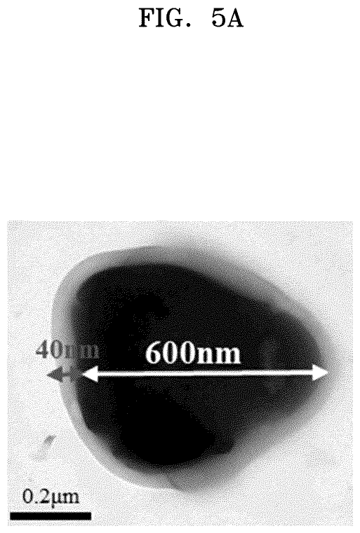

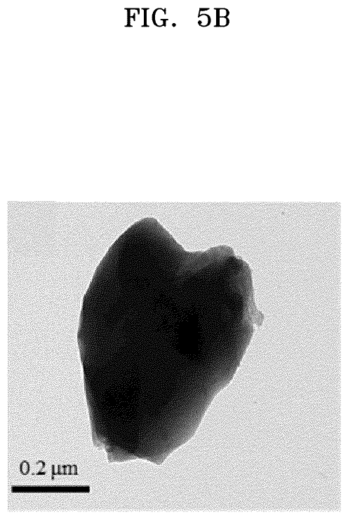

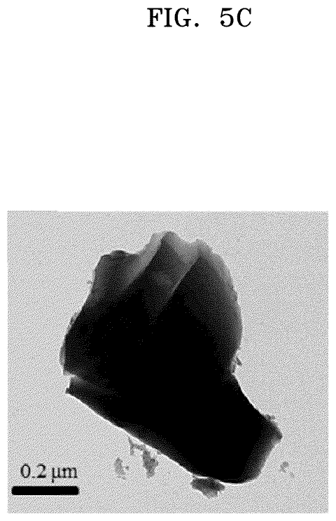

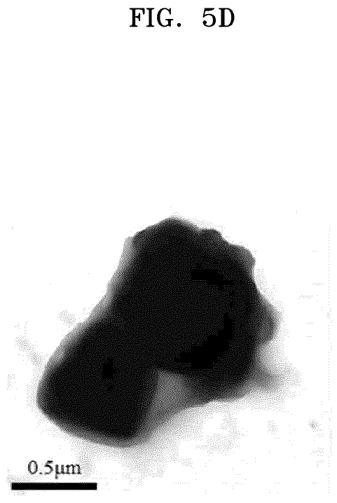

FIGS. 5A to 5D are microscope images of an embodiment of a USTO particle included in the support member 400 of the display apparatus 1. In detail, FIGS. 5A to 5D are transmission electron microscope images of the USTO particle.

The USTO particle may be amorphous, and a size of a STO particle from which a urea coating layer is excluded may be about 200 nm to about 1000 nm. That is, a length of a long axis of the STO particle may be about 200 nm to 1000 nm. In detail, the length of the long axis of the STO particle may be about 500 nm to about 700 nm. In an embodiment, as shown in FIG. 5A, a size of the STO particle disposed in a core of the USTO particle is about 600 nm, and a thickness of a urea layer coated on the STO particle is about 40 nm, for example.

When the dielectric particles 411 are USTO particles, the dielectric particles 411 may have more diverse sizes than when the dielectric particles 411 are STO particles not coated with urea. That is, when the dielectric particles 411 are USTO particles, deviation of sizes of the plurality of dielectric particles 411 may increase.

In general, in the case in which a plurality of particles are mixed with a predetermined solution, the amount of the plurality of particles mixable with a predetermined solution may be greater when the plurality of particles have different sizes than when the plurality of particles have the same size. In an embodiment, when an average of sizes of particles included in a particle group A and an average of sizes of particles included in a particle group B are the same, and deviation of the sizes of the particles included in the particle group A is greater than deviation of the sizes of the particles included in the particle group B, but other conditions except for the deviation of the sizes of the particles are the same, the amount of a plurality of particles mixable with a predetermined solution may be greater in the particle group A than in the particle group B, for example. That is, assuming that the amount of particles of the particle group A to be mixed with 1 milliliter (ml) of a predetermined solution is 1 gram (g), the amount of particles of the particle group B to be mixed with 1 ml of a predetermined solution may be less than 1 g.

Accordingly, when the variable stiffness layer 410 is formed, as deviation of sizes of the dielectric particles 411 increases, the amount of the dielectric particles 411 to be mixed with a material for forming the elastic layer 412 may increase. Accordingly, the amount of the dielectric particles 411 included in the variable stiffness layer 410 may increase. A mass ratio of the dielectric particles 411 to a total mass of the variable stiffness layer 410 may be about 50% to about 80%. In an embodiment, when the dielectric particles 411 are USTO particles, the mass ratio of the dielectric particles 411 to the total mass of the variable stiffness layer 410 may be about 60% to about 70%. In an embodiment, the mass ratio of the dielectric particles 411 to the total mass of the variable stiffness layer 410 may be 65%, for example.

When the mass ratio of the dielectric particles 411 to the total mass of the variable stiffness layer 410 is within the above range, sufficient and uniform stiffness may be imparted to an entirety of the area of the variable stiffness layer 410 when a voltage is applied to the variable stiffness layer 410. When the mass ratio of the dielectric particles 411 to the total mass of the variable stiffness layer 410 is less than the above range, the amount of the dielectric particles 411 with a surface on which polarization is formed may be relatively small when a voltage is applied to the variable stiffness layer 410. Accordingly, even when a voltage is applied to the variable stiffness layer 410, stiffness sufficient to support the display panel 100 by the variable stiffness layer 410 may not be achieved. When the mass ratio of the dielectric particles 411 to the total mass of the variable stiffness layer 410 exceeds the above range, the dielectric particles 411 may not be easily mixed with a material for forming the elastic layer 412 when the variable stiffness layer 410 is formed. Accordingly, the plurality of dielectric particles 411 may not be uniformly distributed within the elastic layer 412.

Thus far, the support member 400 for a display apparatus and the display apparatus 1 including the support member 400 have been described, but the disclosure is not limited thereto. A method of manufacturing the support member for a display apparatus may also fall within the scope of the disclosure. Hereinafter, the method of manufacturing the support member for a display apparatus will be described.

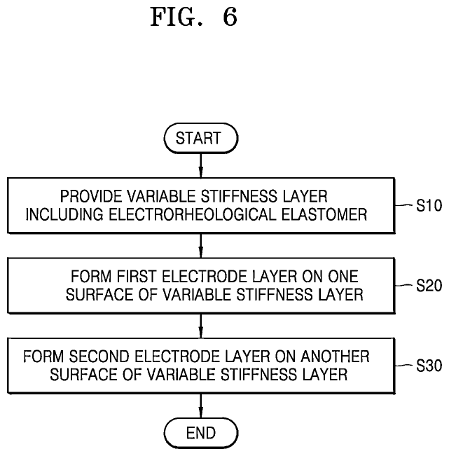

FIG. 6 is a flowchart for explaining an embodiment of a method of manufacturing a support member for a display apparatus.

As shown in FIG. 6, the method of manufacturing a support member for a display apparatus, in an embodiment may include providing a variable stiffness layer including an electrorheological elastomer (S10), forming a first electrode layer on one surface of the variable stiffness layer (S20), and forming a second electrode layer on another surface of the variable stiffness layer (S30).

In the providing the variable stiffness layer including the electrorheological elastomer (S10), the variable stiffness layer 410 including the electrorheological elastomer may be manufactured. First, the dielectric particles 411 may be formed. Then, the electrorheological elastomer may be formed by dispersing the dielectric particles 411 and a curing agent in a polymer solution to prepare an electrorheological fluid, and then curing the electrorheological fluid. The electrorheological elastomer may be formed in a two-dimensional planar structure, and accordingly, the electrorheological elastomer may include the elastic layer 412 including a crosslinked polymer and the dielectric particles 411 dispersed therein. The electrorheological elastomer may function as the variable stiffness layer 410, the stiffness of which changes depending on application of an external voltage.

In an embodiment, the dielectric particles 411 may be formed from a first solution including a titanium dioxide precursor, a solvent, and polyvinylpyrrolidone. That is, the dielectric particles 411 may be titanium dioxide (TiO₂) particles. The electrorheological elastomer may be formed by dispersing titanium dioxide (TiO₂) particles as the dielectric particles 411 and a curing agent in a polydimethylsiloxane solution, and then curing the polydimethylsiloxane solution. That is, the variable stiffness layer 410 may be formed.

The titanium dioxide precursor may be titanium alkoxide, and the solvent may be alcohol. The first solution may further include acetic acid and deionized water. That is, the dielectric particles 411 may be formed from the first solution including titanium alkoxide, polyvinylpyrrolidone, alcohol, organic acid, and deionized water. In an embodiment, titanium dioxide (TiO₂) particles may be formed from the first solution including titanium butoxide, polyvinylpyrrolidone, ethanol, acetic acid, and deionized water, for example. Polypyrrolidone helps titanium dioxide (TiO₂) particles to aggregate. When a concentration of the titanium dioxide precursor in the first solution is sufficiently high, the roughness of a surface of the formed titanium dioxide (TiO₂) particles may be great.

A volume ratio of titanium butoxide and ethanol contained in the first solution may be about 1:1.5 to about 1:2.5. The volume ratio of titanium butoxide and ethanol contained in the first solution may be about 1:1.7 to about 1:2.3. In an embodiment, the volume ratio of titanium butoxide and ethanol contained in the first solution may be 1:2, for example. When the volume ratio of titanium butoxide and ethanol contained in the first solution is within the above range, the roughness of a surface of the formed titanium dioxide (TiO₂) particles may be great. That is, the roughness of the surface of the dielectric particles 411 may be great. In other words, a surface area of the dielectric particles 411 may be large. The surface area of the dielectric particles 411 has been described above with reference to FIG. 2, and thus repetitions in this regard will be omitted. Accordingly, when a voltage is applied to the variable stiffness layer 410, the size of polarization formed on the surface of the dielectric particles 411 may increase, and thus the variable stiffness layer 410 may have relatively great stiffness.

When the volume ratio of titanium butoxide and ethanol contained in the first solution is less than the above range, the possibility of generating other types of byproducts other than titanium dioxide (TiO₂) during a preparation process of titanium dioxide (TiO₂) increases. When the volume ratio of titanium butoxide and ethanol contained in the first solution exceeds the above range, a surface area of the generated dielectric particles 411 may be small. Accordingly, even when a voltage is applied to the variable stiffness layer 410, stiffness sufficient to support the display panel 100 by the variable stiffness layer 410 may not be achieved.

When the dielectric particles 411 are titanium dioxide particles, e.g., a mass ratio of the dielectric particles 411 to a total mass of the variable stiffness layer 410 may be 50%.

In an embodiment, the dielectric particles 411 may be formed by forming strontium titanyl oxalate particles from a second solution including or consisting of titanium halide, strontium halide, oxalic acid, and deionized water, and then coating the strontium titanyl oxalate particles with urea. In an embodiment, the dielectric particles 411 may be formed by forming strontium titanyl oxalate particles from a second solution including or consisting of titanium chloride, strontium chloride, oxalic acid, and deionized water, and then coating the strontium titanyl oxalate particles with urea. That is, the dielectric particles 411 may be USTO particles, for example. An electrorheological elastomer may be formed by dispersing USTO particles as the dielectric particles 411 and a curing agent in a polydimethylsiloxane solution, and then curing the polydimethylsiloxane solution. That is, the variable stiffness layer 410 may be formed.

When the dielectric particles 411 are USTO particles, the mass ratio of the dielectric particles 411 to the total mass of the variable stiffness layer 410 may be about 60% to about 70%. The amount of the dielectric particles 411 dispersed in the polydimethylsiloxane solution may be appropriately adjusted to allow the content of the dielectric particles 411 in the variable stiffness layer 410 to satisfy the above range.

In the forming the first electrode layer on one surface of the variable stiffness layer (S20), the first electrode layer 420 may be formed using various methods such as a deposition method, a coating method, and an adhesion method. In an embodiment, the first electrode layer may be formed via deposition on an entirety of the surface of one surface of the variable stiffness layer 410 using a sputtering method or the like in a chamber, for example. A material for forming the first electrode layer may include at least one of ITO, IZO, TAO, TO, zinc oxide (ZnO), graphene, CNT, and silver nanowire. In an alternative embodiment, the material for forming the first electrode layer may include at least one of copper (Cu), aluminum (Al), platinum (Pt), silver (Ag), gold (Au), and nickel (Ni).

In the forming the second electrode layer on another surface of the variable stiffness layer (S30), the second electrode layer 430 may be formed on a surface opposite to one surface of the variable stiffness layer 410, on which the first electrode layer 420 is formed, using various methods such as a deposition method, a coating method, and an adhesion method. In an embodiment, the second electrode layer may be formed via deposition on the entirety of the surface of another surface of the variable stiffness layer 410 using a sputtering method or the like in a chamber, for example. A material for forming the second electrode layer may include at least one of ITO, IZO, TAO, TO, zinc oxide (ZnO), graphene, CNT, and silver nanowire. In an alternative embodiment, the material for forming the second electrode layer may include at least one of copper (Cu), aluminum (Al), platinum (Pt), silver (Ag), gold (Au), and nickel (Ni).

Hereinafter, the disclosure will be described in more detail by Examples and Comparative Examples below. However, Examples below are intended to illustrate the disclosure, and the disclosure is not limited to Examples below.

### Embodiment 1

### Preparation of Titanium Dioxide (TiO₂) Particles

A solution A was prepared by mixing 170 ml of ethanol and 2.0 g of polyvinylpyrrolidone, and then stirring the combination for 5 minutes at 25 degrees Celsius (° C.) and 1000 revolutions per minute (rpm). A solution B was prepared by adding 85 ml of titanium butoxide to the solution A, and then stirring the resulting material for 5 minutes at 1000 rpm and adding 0.5 ml of acetic acid during the stirring process. Titanium dioxide (TiO₂) particles were prepared by adding 35 m of deionized water to the solution B using a drop-funnel to prepare a solution C and stirring the resulting material for 12 hours at 600 rpm. A volume ratio of titanium butoxide and ethanol contained in the solution C was 1:2. Titanium dioxide (TiO₂) particles were obtained using centrifugation. The obtained titanium dioxide (TiO₂) particles were dried in a vacuum oven for 24 hours at 60° C.

### Preparation of Electrorheological Elastomer Including Titanium Dioxide (TiO₂) Particles

After titanium dioxide (TiO₂) particles were processed in the form of powder and the titanium dioxide (TiO₂) particles in the form of powder were added to a polydimethylsiloxane (Sylgard 184) solution, the resulting material was dispersed using a homogenizer for 20 minutes at 1000 rpm or less, a curing agent was added thereto, and then the resulting material was dispersed for 10 minutes at 1000 rpm or less. A mass ratio of the curing agent and the polydimethylsiloxane solution was 1:1. An electrorheological elastomer was prepared by curing the polydimethylsiloxane solution in which the titanium dioxide (TiO₂) particles and the curing agent are dispersed between press frames using a heating press for 30 minutes at 120° C. A thickness of the electrorheological elastomer was 0.3 millimeter (mm). A mass ratio of the titanium dioxide (TiO₂) particles to a total mass of the electrorheological elastomer was 50%.

### Preparation of Support Member Including Titanium Dioxide (TiO₂) Particles

An organic film with one surface on which ITO is deposited was attached to one surface of the electrorheological elastomer including titanium dioxide (TiO₂) particles using a PSA. Then, a support member including the titanium dioxide (TiO₂) particles was prepared by attaching an organic film with one surface on which ITO is deposited to another surface of the electrorheological elastomer including the titanium dioxide (TiO₂) particles by a PSA. However, the disclosure is not limited thereto. ITO may be deposited on one surface of the electrorheological elastomer including the titanium dioxide (TiO₂) particles and then ITO may be deposited on another surface of the electrorheological elastomer including the titanium dioxide (TiO₂) particles.

### Embodiment 2

### Preparation of USTO Particles

A solution 1 was prepared by immersing a flask containing 100 g of deionized water in ice water, adding 22 ml of titanium chloride to the deionized water using a drop-funnel, and stirring the resulting material. A solution 2 was prepared by dissolving 31.7 g of strontium chloride in 100 g of deionized water at 25° C. A solution 3 was prepared by dissolving 36 g of oxalic acid in 100 g of deionized water at 60° C. A solution 4 was prepared by dissolving 40 g of urea in 100 g of deionized water. A solution 5 was prepared by sequentially adding the solutions 1 and 2 to the solution 3 at 60° C., and then stirring the resulting material for 30 minutes. 300 g of ethanol was added to the solution 5 and then stirred for 2 hours. USTO, i.e., strontium titanyl oxalate particles coated with urea, were prepared by adding the solution 4 to the solution 5, and then stirring the resulting material for 30 minutes. The USTO particles were obtained using centrifugation. The obtained USTO particles were dried in a vacuum oven for 24 hours at 60° C.

### Preparation of Electrorheological Elastomer Including USTO Particles

After USTO particles were processed in the form of powder and the USTO particles in the form of powder were added to a polydimethylsiloxane (Sylgard 184) solution, the resulting material was dispersed using a homogenizer for 20 minutes at 1000 rpm or less, a curing agent was added thereto, and then the resulting material was dispersed for 10 minutes at 1000 rpm or less. A mass ratio of the curing agent and the polydimethylsiloxane solution was 1:5. An electrorheological elastomer was prepared by curing the polydimethylsiloxane solution in which the USTO particles and the curing agent are dispersed between press frames using a heating press for 30 minutes at 120° C. A thickness of the electrorheological elastomer was 0.5 mm. A mass ratio of the USTO particles to a total mass of the electrorheological elastomer was 65%.

### Preparation of Support Member Including USTO Particles

An organic film with one surface on which ITO is deposited was attached to one surface of the electrorheological elastomer including USTO particles using a PSA. Then, a support member including the USTO particles was prepared by attaching an organic film with one surface on which ITO is deposited to another the electrorheological elastomer including the USTO particles by a PSA. However, the disclosure is not limited thereto. ITO may be deposited on one surface of the electrorheological elastomer including the USTO particles and then ITO may be deposited on another surface of the electrorheological elastomer including the USTO particles.

### Comparative Example 1

A preparation method of Comparative Example 1 is different from the preparation method of Embodiment 1 in that polyvinylpyrrolidone is not used and a volume ratio of titanium butoxide and ethanol is 1:30 during a preparation process of the titanium dioxide (TiO₂) particles. That is, a solution B′ was prepared by adding 85 ml of titanium butoxide to a solution A′ that is 2550 ml of ethanol, and then stirring the resulting material for 5 minutes at 1000 rpm and adding 7.5 ml of acetic acid during the stirring process. Titanium dioxide (TiO₂) particles were prepared by adding 35 m of deionized water to the solution B′ using a drop-funnel to prepare a solution C′ and stirring the resulting material for 12 hours at 600 rpm. That is, a volume ratio of titanium butoxide and ethanol contained in the solution C′ was 1:30. Titanium dioxide (TiO₂) particles were obtained using centrifugation. The obtained titanium dioxide (TiO₂) particles were dried in a vacuum oven for 24 hours at 60° C. In the preparation method of Comparative Example 1, a preparation process of an electrorheological elastomer including titanium dioxide (TiO₂) particles and a preparation process of a support member including titanium dioxide (TiO₂) particles are the same as those of Embodiment 1, and thus repeated descriptions in this regard will be omitted.

Table 1 shows a predetermined surface area, pore size, and pore volume of the dielectric particles 411 included in each of Embodiment 1 and Comparative Example 1. The predetermined surface area in Table 1 refers to a total surface area of the plurality of dielectric particles 411 per unit mass. The pore size in Table 1 refers to an average value of sizes of a plurality of pores included in the dielectric particles 411, and the pore volume in Table 1 refers to a total volume of a plurality of pores included in the dielectric particles 411 per unit mass. The predetermined surface area, pore size and pore volume of the dielectric particles 411 were determined through Brunauer-Emmett-Teller (“BET”) measurement. The BET measurement is a general content in measurement of a surface area of a particle, and thus a detailed description thereof will be omitted.

TABLE 1

| | Predetermined | | |
|---|---|---|---|
| | surface area | Pore size | Pore volume |
| Comparative | 341.98 m²/g | 2.24 nm | 0.19 cm³/g |
| Example 1 | | | |
| Embodiment 1 | 403.39 m²/g | 2.39 nm | 0.24 cm³/g |

Referring to Table 1, the dielectric particles of Comparative Example 1 have a predetermined surface area of 341.98 m²/g, a pore size of 2.24 nm, and a pore volume of 0.19 cm³/g. The dielectric particles 411 of Embodiment 1 have a predetermined surface area of 403.39 m²/g, a pore size of 2.39 nm, and a pore volume of 0.24 cm³/g.

The pore size of the dielectric particles 411 in Embodiment 1 is similar to that of the dielectric particles in Comparative Example 1, but the pore volume of the dielectric particles 411 in Embodiment 1 is greater than that of the dielectric particles in Comparative Example 1. Therefore, the dielectric particles 411 of Embodiment 1 have more pores than the dielectric particles of Comparative Example 1, and the surface area of the dielectric particles 411 of Embodiment 1 is larger than that of the dielectric particles of Comparative Example 1. Accordingly, the magnitude of polarization formed on a surface of the dielectric particles 411 of Embodiment 1 may be greater than the magnitude of polarization formed on a surface of the dielectric particles of Comparative Example 1. Accordingly, when a voltage is applied to the variable stiffness layer 410 of Embodiment 1, the variable stiffness layer 410 may have relatively great stiffness.

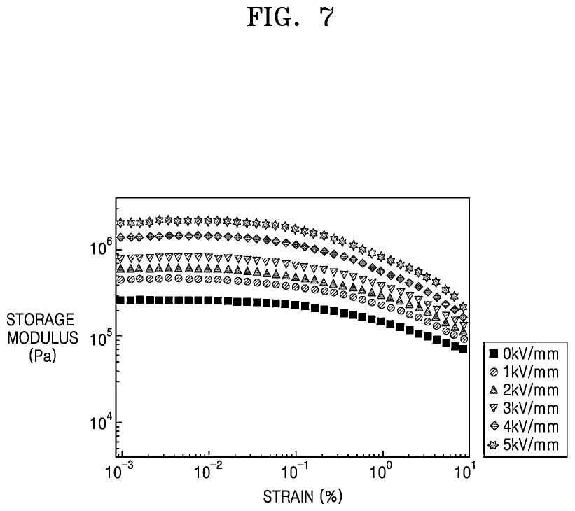

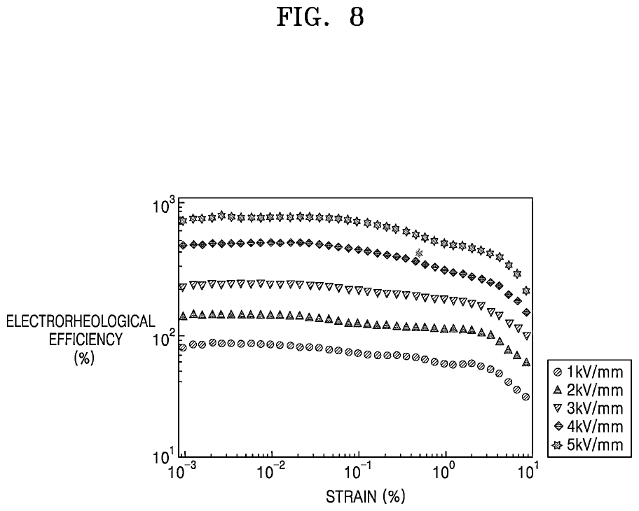

FIG. 7 is a graph showing an embodiment of a storage modulus of the support member 400 for a display apparatus. FIG. 8 is a graph showing an embodiment of an electrorheological efficiency of the support member 400 for a display apparatus. In detail, FIG. 7 is a graph showing a storage modulus of Embodiment 1. FIG. 8 is a graph showing an electrorheological efficiency of Embodiment 1.

As shown in FIG. 7, voltages of 0 kilovolt per millimeter (kV/mm), 1 kV/mm, 2 kV/mm, 3 kV/mm, 4 kV/mm, and 5 kV/mm were each applied in Embodiment 1. That is, voltages of 0 kV, 1 kV, 2 kV, 3 kV, 4 kV, and 5 kV per unit thickness of Embodiment 1 were each applied in Embodiment 1. In other words, as described above, Embodiment 1 has a thickness of 0.3 mm, and thus voltages of 0 kV, 0.3 kV, 0.6 kV, 0.9 kV, 1.2 kV, and 1.5 kV were each applied in Embodiment 1. FIG. 8 shows an electrorheological efficiency of the support member 400 for a display apparatus when voltages of 1 kV/mm, 2 kV/mm, 3 kV/mm, 4 kV/mm, and 5 kV/mm were each applied in Embodiment 1.

When a storage modulus when a voltage is applied to the variable stiffness layer 410 is G and a storage modulus when no voltage is applied to the variable stiffness layer 410 is G₀, an electrorheological efficiency (ER eff) of the support member 400 including the variable stiffness layer 410 may satisfy [Equation 1] below.

$$ER eff = \frac{G - {G}_{0}}{{G}_{0}} \times 100 \% \qquad [ Equation 1 ]$$

As shown in FIG. 7, when no voltage was applied in Embodiment 1 (e.g., when a voltage of 0 kV/mm was applied), Embodiment 1 had a storage modulus of about 0.26 megapascal (MPa). When a voltage of 5 kV/mm was applied in Embodiment 1, Embodiment 1 had a storage modulus of about 2.18 MPa. Accordingly, when a voltage of 5 kV/mm was applied in Embodiment 1, Embodiment 1 had an electrorheological efficiency of about 740%. That is, the dielectric particles 411 of Embodiment 1 have a relatively large surface area, and thus when a voltage is applied to the variable stiffness layer 410 of Embodiment 1, the variable stiffness layer 410 may have relatively great stiffness.

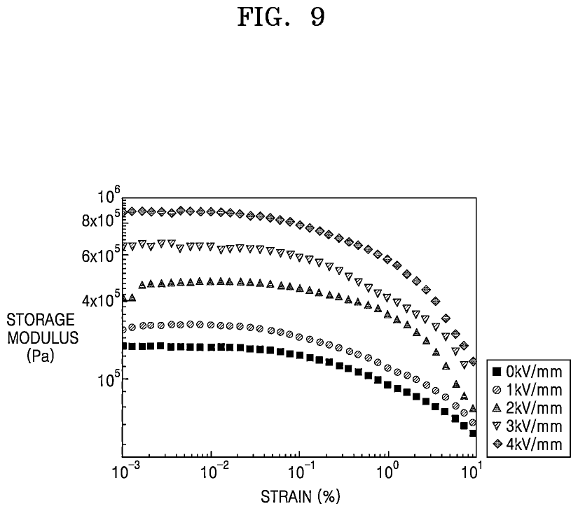

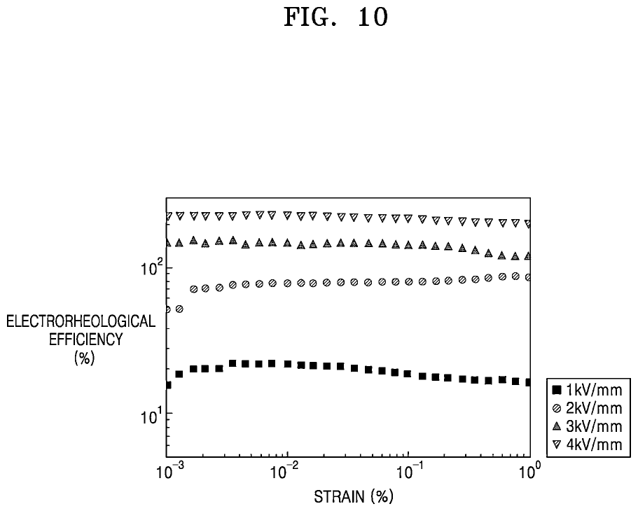

FIG. 9 is a graph showing an embodiment of a storage modulus of the support member 400 for a display apparatus. FIG. 10 is a graph showing an embodiment of an electrorheological efficiency of the support member 400 for a display apparatus. In detail, FIG. 9 is a graph showing a storage modulus of Embodiment 2. FIG. 10 is a graph showing an electrorheological efficiency of Embodiment 2.

As shown in FIG. 9, voltages of 0 kV/mm, 1 kV/mm, 2 kV/mm, 3 kV/mm, and 4 kV/mm were each applied in Embodiment 2. That is, voltages of 0 kV, 1 kV, 2 kV, 3 kV, and 4 kV per unit thickness were each applied in Embodiment 2. In other words, as described above, Embodiment 2 has a thickness of 0.5 mm, and thus voltages of 0 kV, 0.5 kV, 1.0 kV, 1.5 kV, and 2.0 kV were each applied in Embodiment 2. FIG. 10 shows an electrorheological efficiency of the support member 400 for a display apparatus when voltages of 1 kV/mm, 2 kV/mm, 3 kV/mm, and 4 kV/mm are each applied in Embodiment 2.

As shown in FIG. 9, when no voltage was applied in Embodiment 2 (e.g., when a voltage of 0 kV/mm was applied), Embodiment 2 had a storage modulus of about 0.26 MPa. When a voltage of 5 kV/mm was applied in Embodiment 2, Embodiment 2 had a storage modulus of about 0.9 MPa. Accordingly, when a voltage of 5 kV/mm was applied in Embodiment 2, Embodiment 2 had an electrorheological efficiency of about 250%. That is, Embodiment 2 has relatively many dielectric particles 411, and thus when a voltage is applied to the variable stiffness layer 410 of Embodiment 2, the variable stiffness layer 410 may have relatively great stiffness.

According to the disclosure, when a voltage is applied to the variable stiffness layer 410 of the support member 400, the variable stiffness layer 410 may be relatively rigid. Thus, even when the support member 400 does not include metal bars, the support member 400 may support the display panel 100. Therefore, since no step difference is recognized in an area between the metal bars, the display quality of the display apparatus 1 may be improved.

In an embodiment configured as described above, a support member for a display apparatus, the display quality of which is improved, a display apparatus including the same, and a method of manufacturing the support member for a display apparatus may be implemented. Needless to say, the scope of the disclosure is not limited by the effect.

As such, the disclosure has been described with reference to the embodiments shown in the drawings, but this is only exemplary, and those skilled in the art will understand that various modifications and equivalent other embodiments are possible therefrom. Therefore, the true technical scope of the disclosure should be determined by the technical spirit of the appended claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A support member comprising:
a variable stiffness layer including an electrorheological elastomer;
a first electrode layer disposed on a first surface of the variable stiffness layer; and
a second electrode layer disposed on a second surface of the variable stiffness layer different from the first surface of the variable stiffness layer.

2. The support member of claim 1, wherein the electrorheological elastomer includes an elastic layer and dielectric particles disposed within the elastic layer.

3. The support member of claim 2, wherein the dielectric particles each include titanium dioxide.

4. The support member of claim 3, wherein the dielectric particles each have a predetermined surface area of about 380.00 square meters per gram to about 420.00 square meters per gram.

5. The support member of claim 3, wherein the dielectric particles each include a plurality of pores,
an average of sizes of the plurality of pores is about 2.25 nanometers to about 2.55 nanometers, and
a volume of the plurality of pores is about 0.20 cubic centimeter per gram to about 0.30 cubic centimeter per gram.

6. The support member of claim 2, wherein the dielectric particles each include urea and strontium titanyl oxalate.

7. The support member of claim 6, wherein a mass ratio of the dielectric particles to a total mass of the variable stiffness layer is about 60% to about 70%.

8. The support member of claim 2, wherein the elastic layer includes polydimethylsiloxane.

9. A display apparatus comprising:
a display panel including a display element; and
a support member disposed below the display panel, the support member including:
a variable stiffness layer including an electrorheological elastomer;
a first electrode layer disposed on a first surface of the variable stiffness layer; and
a second electrode layer disposed on a second surface of the variable stiffness layer different from the first surface of the variable stiffness layer.

10. The display apparatus of claim 9, wherein the variable stiffness layer includes dielectric particles and an elastic layer in which the dielectric particles are disposed.

11. The display apparatus of claim 10, wherein the dielectric particles each include titanium dioxide.

12. The display apparatus of claim 11, wherein the dielectric particles each have a predetermined surface area of about 380.00 square meters per gram to about 420.00 square meters per gram.

13. The display apparatus of claim 11, wherein the dielectric particles each include a plurality of pores,
an average of sizes of the plurality of pores is about 2.25 nanometers to about 2.55 nanometers, and
a volume of the plurality of pores is about 0.20 cubic centimeters per gram to about 0.30 cubic centimeters per gram.

14. The display apparatus of claim 10, wherein the dielectric particles each include urea and strontium titanyl oxalate.

15. The display apparatus of claim 14, wherein a mass ratio of the dielectric particles to a total mass of the variable stiffness layer is about 60% to about 70%.

16. The display apparatus of claim 10, wherein the elastic layer includes polydimethylsiloxane.

17. The display apparatus of claim 9, further comprising an adhesive layer disposed between the display panel and the support member.

18. A method of manufacturing a support member, the method comprising:
providing a variable stiffness layer including an electrorheological elastomer;
forming a first electrode layer on a first surface of the variable stiffness layer; and
forming a second electrode layer on a second surface of the variable stiffness layer different from the first surface of the variable stiffness layer.

19. The method of claim 18, wherein the providing the variable stiffness layer comprises:
forming dielectric particles from a first solution including titanium alkoxide, polyvinylpyrrolidone, alcohol, organic acid, and deionized water; and
forming the electrorheological elastomer by dispersing the dielectric particles and a curing agent in a polydimethylsiloxane solution, and then curing the polydimethylsiloxane solution.

20. The method of claim 19, wherein a volume ratio of titanium butoxide to ethanol in the first solution is about 1:1.5 to about 1:2.5.

21. The method of claim 18, wherein the providing the variable stiffness layer comprises:
forming dielectric particles by forming strontium titanyl oxalate particles from a second solution including titanium halide, strontium halide, oxalic acid, and deionized water, and then coating the strontium titanyl oxalate particles with urea; and
forming the electrorheological elastomer by dispersing the dielectric particles and a curing agent in a polydimethylsiloxane solution, and then curing the polydimethylsiloxane solution.

22. The method of claim 21, wherein a mass ratio of the dielectric particles to a total mass of the variable stiffness layer is about 60% to about 70%.
